(19) United States
(12) Patent Application Publication
(10) Pub. No.: US 2012/0168725 A1
(43) Pub. Date: Jul. 5, 2012

(54) ORGANIC ELECTROLUMINESCENT DEVICE

(75) Inventors: Chang-Ting Lin, Hsinchu County (TW); Shih-Feng Hsu, Taoyuan County (TW)

(73) Assignee: AU OPTRONICS CORPORATION, Hsinchu (TW)

(21) Appl. No.: 13/088,408

(22) Filed: Apr. 17, 2011

(30) Foreign Application Priority Data
Dec. 31, 2010 (TW) 99147241

(51) Int. Cl. H01L 51/54

(52) U.S. Cl. 257/40; 257/E51.028

(57) ABSTRACT

An organic electroluminescent device including a first electrode layer, a second electrode layer, a light emitting layer and a hole injection layer is provided. The light emitting layer is disposed between the first electrode layer and the second electrode layer. The hole injection layer is disposed between the first electrode layer and the light emitting layer, wherein the hole injection layer includes a first material layer and a second material layer. The second material layer is disposed on the first material layer and includes a main material and a doping material, wherein the doping material of the second material layer and a material of the first material layer are substantially the same.

### CROSS-REFERENCE TO RELATED APPLICATION

This application claims the priority benefit of Taiwan application serial no. 99147241, filed Dec. 31, 2010. The entirety of the above-mentioned patent application is hereby incorporated by reference herein and made a part of this specification.

### BACKGROUND OF THE INVENTION

1. Field of the Invention

The disclosure is related to an organic electroluminescent device, and in particular to an organic electroluminescent device which has greater hole injection efficiency.

2. Description of Related Art

Electroluminescent devices are a type of semiconductor device which is capable of converting electricity into light and has high conversion efficiency. Electroluminescent devices are commonly used as emitting devices in indicator lights, display panels, and optical reading and writing heads. Electroluminescent devices have characteristics such as having no viewing angle problems, simple manufacturing processes, low cost, high response speed, wide operating temperature ranges, and full color, electroluminescent devices comply with requirements for displays in the multi-media age and have the potential to become the mainstream among next generation flat panel displays.

Generally, an electroluminescent device includes an anode, a light emitting layer, and a cathode. The principle of emission by an electroluminescent device is that holes and electrons are injected into the light emitting layer from the anode and the cathode, respectively. When electrons and holes are joined in the light emitting layer, they are combined to form photons, thereby emitting light. In order to smoothly inject electrons and holes from the electrodes into the light emitting layer at a lower driving voltage, an electron injection layer and an electron transport layer may be further disposed between the anode and the light emitting layer, and a hole injection layer and a hole transport layer may be further disposed between the cathode and the light emitting layer. The electron injection layer and the electron transport layer have p-type dopants, the hole injection layer and the hole transport layer have n-type dopants, and the dopants are usually formed in the material layers by way of co-evaporation.

However, the p-type dopants currently used in the hole injection layer have disadvantages such as inferior thermal stability, being prone to crystallization, and being unsuitable for optical tooling, so that the electroluminescent device has inferior hole injection efficiency and a short lifetime.

### SUMMARY OF THE INVENTION

The disclosure provides an organic electroluminescent device which has enhanced light emitting efficiency, a lower driving voltage, and a longer lifetime.

The disclosure provides an organic electroluminescent device. The organic electroluminescent device includes a first electrode layer, a second electrode layer, a light emitting layer, and a hole injection layer. The light emitting layer is disposed between the first electrode layer and the second electrode layer. The hole injection layer is disposed between the first electrode layer and the light emitting layer and includes a first material layer and a second material layer. The second material layer is disposed on the first material layer and includes a main material and a doping material, wherein the doping material of the second material layer and a material of the first material layer are substantially the same.

According to an embodiment of the disclosure, the first material layer and the doping material of the second material layer include an organic material.

According to an embodiment of the invention, the above organic material has a chemical formula of Formula 1,

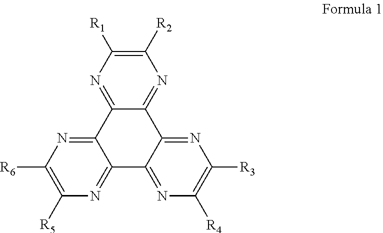

wherein each of R₁-R₆ independently represents hydrogen, a halogen, —CN, —NO₂, —SO₂R, SOR, —CF₃, —CO—OR, —CO—NHR, CO—NRR′, a substituted or non-substituted aryl group, a substituted or non-substituted heteroaryl group, or a substituted or non-substituted alkyl group, and each of R and R′ independently represents a substituted or non-substituted aryl group or a substituted or non-substituted alkyl group, or wherein R₁ and R₂, R₃ and R₄, or R₅ and R₆ form a ring structure which includes an aromatic ring, a heteroaromatic ring, or a non-aromatic ring, and the ring structure is substituted or non-substituted.

According to an embodiment of the disclosure, the above doping material and the material of the first material layer include:

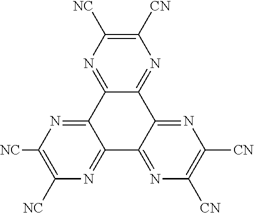

According to an embodiment of the disclosure, the main material of the second material layer includes a triarylamine.

According to an embodiment of the disclosure, a content of the doping material in the second material layer is less than 10%.

According to an embodiment of the disclosure, the content of the doping material in the second material layer is from 0.5% to 10%.

According to an embodiment of the disclosure, a work function value of the first material layer is greater than 5 eV.

According to an embodiment of the disclosure, the first material layer contacts the first electrode layer.

According to an embodiment of the disclosure, the organic electroluminescent device further includes a hole transport layer, disposed between the hole injection layer and the light emitting layer.

According to an embodiment of the disclosure, the organic electroluminescent device further includes an electron transport layer, disposed between the second electrode layer and the light emitting layer.

According to an embodiment of the disclosure, the organic electroluminescent device further includes an electron injection layer, disposed between the second electrode layer and the light emitting layer.

In summary, in the organic electroluminescent device according to the disclosure, the hole injection layer includes the first material layer and the second material layer, and the doping material of the second material layer and the material of the first material layer are substantially the same, so that the hole injection efficiency is enhanced. Therefore, the organic electroluminescent device has enhanced light emitting efficiency, a lower driving voltage, and a longer lifetime.

In order to make the aforementioned and other objects, features and advantages of the disclosure comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional diagram showing an organic electroluminescent device according to an embodiment of the disclosure.

FIG. 2 is a schematic cross-sectional diagram showing an organic electroluminescent device according to another embodiment of the disclosure.

FIGS. 3A and 3B are graphs which respectively show curves which represent current density versus voltage (J-V curves) and curves which represent luminance versus time according to experimental embodiment 1 and comparative embodiment 1.

FIG. 4 is a graph illustrating curves which represent light emitting efficiency versus luminance according to experimental embodiment 1 and comparative embodiment 2.

### DESCRIPTION OF EMBODIMENTS

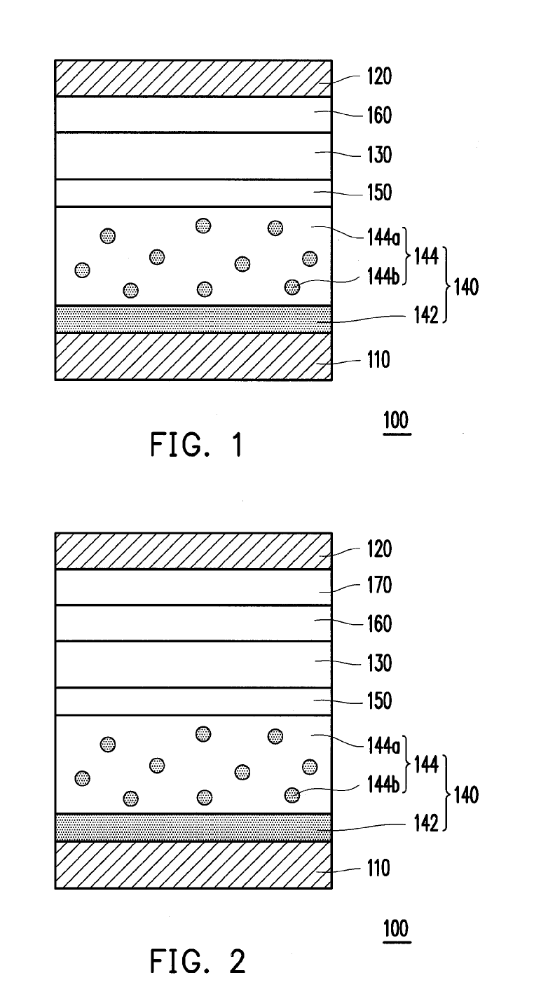

FIG. 1 is a schematic cross-sectional diagram showing an organic electroluminescent device according to an embodiment of the disclosure. Referring to FIG. 1, an organic electroluminescent device 100 includes a first electrode layer 110, a second electrode layer 120, a light emitting layer 130, and a hole injection layer 140.

According to the present embodiment, the first electrode layer 110 is used as an anode of the organic electroluminescent device 100, and second electrode layer 120 is used as a cathode of the organic electroluminescent device 100. The light emitting layer 130 is disposed between the first electrode layer 110 and the second electrode layer 120. According to the present embodiment, a material of the first electrode layer 110 and the second electrode layer 120 is, for example, a transparent electrode layer or a non-transparent electrode layer. The transparent electrode layer is, for example, a metal oxide layer which includes indium tin oxide, indium zinc oxide, aluminum tin oxide, aluminum zinc oxide, indium-gallium-zinc oxide, another suitable metal oxide, or a stacked layer of at least two of the above. The transparent electrode layer may also be a highly transparent thin metal layer or stacked thin metal layer. A material of the non-transparent electrode layer is, for example, copper, aluminum, silver, gold, titanium, molybdenum, tungsten, chromium, an alloy of the above, or a stacked layer of the above. The light emitting layer 130 is a white light emitting material layer or an emitting material layer of other colored lights (such as red, green, or blue).

The hole injection layer 140 is disposed between the first electrode layer 110 and the light emitting layer 130 and includes a first material layer 142 and a second material layer 144. The second material layer 144 is disposed on the first material layer 142 and includes a main material 144a and a doping material 144b, wherein the doping material 144b of the second material layer 144 and a material of the first material layer 142 are substantially the same. According to the present embodiment, the first material layer 142 is, for example, disposed between the second material layer 144 and the first electrode layer 110, and the first material layer 142 contacts, for example, the first electrode layer 110. In other words, the first material layer 142 and the second material layer 144 are sequentially stacked on the first electrode layer 110.

According to the present embodiment, a work function value of the first material layer 142 is, for example, greater than 5 eV. The material of the first material layer 142 and the doping material 144b of the second material layer 144 include, for example, an organic material. The organic material has a chemical formula of Formula 1.

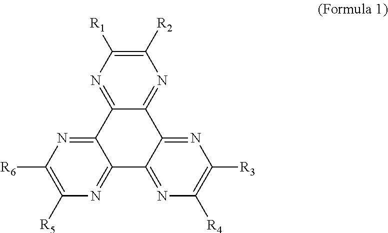

Each of R₁-R₆ independently represents hydrogen, a halogen, —CN, —NO₂, —SO₂R, SOR, —CF₃, —CO—OR, —CO—NHR, CO—NRR′, a substituted or non-substituted aryl group, a substituted or non-substituted heteroaryl group, or a substituted or non-substituted alkyl group, and each of R and R′ independently represents a substituted or non-substituted aryl group or a substituted or non-substituted alkyl group.

Alternatively, R₁ and R₂, R₃ and R₄, or R₅ and R₆ form a ring structure which includes an aromatic ring, a heteroaromatic ring, or a non-aromatic ring, and the ring structure is substituted or non-substituted. For example, the material of the first material layer 142 and the doping material 144b of the second material layer 144 include HAT-CN and have the following structure.

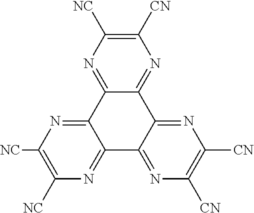

According to the present embodiment, the main material of the second material layer 144 includes, for example, a triarylamine organic compound such as N,N′-diphenyl-N,N′-bis(1-naphthyl)-(1,1′-biphenyl)-4,4′-diamine (NPB) or 4,4′,4″-Tris-(N-(naphthylen-2-yl)-N-phenylamine)triphenylamine (2-TNATA). A content of the doping material 144b in the second material layer 144 is, for example, less than 10%. The content of the doping material 144b in the second material layer 144 is, for example, from 0.5% to 10%.

According to the present embodiment, a method of forming the first material layer 142 and the second material layer 144 is, for example, evaporation or another suitable method. The following describes evaporation as an example.

An evaporation source used to form the first material layer 142 includes an evaporation material, and a co-evaporation source used to form the second material layer 144 includes a main evaporation material and a doping evaporation material. The evaporation material used to form the first material layer 142 and the doping evaporation material used to form the second material layer 144 are substantially the same, so that the doping material 144b of the second material layer 144 and the material of the first material layer 142 are substantially the same. In particular, according to the present embodiment, the doping material 144b of the second material layer 144 and the material of the first material layer 142 are, for example, thermally stable, so as to facilitate evaporation and so that the first material layer 142 and the second material layer 144 are thermally stable.

According to the present embodiment, the organic electroluminescent device 100 further includes, for example, a hole transport layer 150 and an electron transport layer 160, so as to increase light emitting efficiency of the light emitting layer 130. The hole transport layer 150 is, for example, disposed between the hole injection layer 140 and the light emitting layer 130, and the electron transport layer 160 is, for example, disposed between the second electrode layer 120 and the light emitting layer 130. According to another embodiment, as shown in FIG. 2, the organic electroluminescent device 100 further includes, for example, an electron injection layer 170. The electron injection layer 170 is, for example, disposed between the second electrode layer 120 and the light emitting layer 130. In detail, the electron injection layer 170 is, for example, disposed between the second electrode layer 120 and the electron transport layer 160 and contacts, for example, the second electrode layer 120, so as to increase light emitting efficiency of the light emitting layer 130. It should be particularly noted that although the organic electroluminescent device 100 shown in FIGS. 1 and 2 includes the hole transport layer 150, the electron transport layer 160, and the electron injection layer 170, according to another embodiment, the organic electroluminescent device may also not include at least one of the hole transport layer, the electron transport layer, and the electron injection layer. It should be particularly noted that according to the present embodiment, the organic electroluminescent device 100 may be used, for example, in a display, and particularly in an active matrix organic light-emitting display (AMOLED).

In the organic electroluminescent device 100 according to the present embodiment, the electron injection layer 140 which includes the first material layer 142 and the second material layer 144 is disposed on the first electrode layer 110, and the doping material 144b of the second material layer 144 and the material of the first material layer 142 are substantially the same. The material of the first material layer 142 and the doping material 144b (such as the organic material which has the chemical formula of Formula 1) of the second material layer 144 have, for example, a suitable work function value (for example, greater than 5 eV) and a good charge conductivity. Therefore, since the first material layer 142 has a lower energy barrier, holes are injected from the first electrode layer 110 (the anode layer) into the hole injection layer 140 more easily, thereby enhancing hole injection efficiency of the hole injection layer 140. Moreover, by utilizing the material of the first material layer 142, optical characteristics of displays such as top-emitting organic light-emitting displays are easily optimized.

On the other hand, the doping material 144b of the second material layer 144 and the material of the first material layer 142 are substantially the same, and the energy barrier between the two layers is reduced, so that a hole concentration of the hole injection layer 140 is increased. In other words, the arrangement of the hole injection layer 140 enables the holes to have better mobility, so that the mobility of the holes are, for example, greater than the mobility of the electrons. Therefore, the organic electroluminescent device 100 is suitable for a lower device driving voltage and thus prevents an increase in operating voltage, thereby extending the lifetime of the organic electroluminescent device 100. Furthermore, the material of the first material layer 142 and the doping material 144b of the second material layer 144 are, for example, more thermally stable and able to be optically processed, so that the hole injection layer 140 are more thermally stable and a film thickness thereof is able to be correctly measured. In other words, the organic electroluminescent device according to the present embodiment has better device characteristics.

The following describes multiple experimental embodiments to verify the effects described by the disclosure.

### Experimental Embodiment 1

In order to verify that the organic electroluminescent device according to the above embodiments has better device characteristics and a longer lifetime, experimental embodiment 1 is compared with comparative embodiment 1. The organic electroluminescent device according to experimental embodiment 1 has a structure as shown in FIG. 1, wherein the material of the first material layer and the doping material of the second material layer are the above-mentioned HAT-CN, a thickness of the first material layer is 30 nm, and a doping concentration and a thickness of the second material layer are respectively 1.5% and 150 nm. The organic electroluminescent device according to comparative embodiment 1 has a structure as shown in FIG. 1, wherein the material of the first material layer is HAT-CN, a thickness of the first material layer is 30 nm, the doping material of the second material layer includes tetrafluoro-tetracyano-quinodimethane (F4-TCNQ), and the doping concentration and the thickness of the second material layer are respectively 1.5% and 150 nm. F4-TCNQ is a conventional and common doping material used in the hole injection layer and has drawbacks such as inferior thermal stability, being prone to crystallization, and being unsuitable for optical tooling.

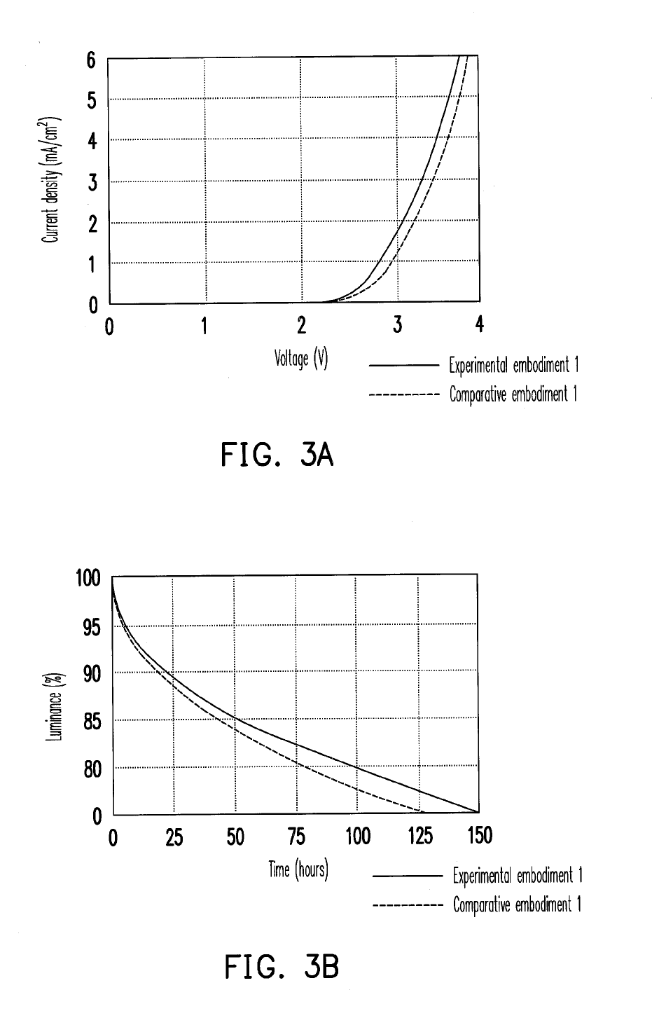

FIGS. 3A and 3B are graphs which respectively show curves which represent current density versus voltage (J-V curves) and curves which represent luminance versus time according to experimental embodiment 1 and comparative embodiment 1. According to FIG. 3A, the light emitting efficiency of the organic electroluminescent device according to experimental embodiment 1 is greater than the light emitting efficiency of the organic electroluminescent device according to comparative embodiment 1. On the other hand, according to FIG. 3B, compared to the organic electroluminescent device in comparative embodiment 1, the organic electroluminescent device in experimental embodiment 1 has a longer lifetime, and the lifetime of the organic electroluminescent device in experimental embodiment 1 is 1.2 times the lifetime of the organic electroluminescent device in comparative embodiment 1. In other words, compared with a hole injection layer of a conventional organic electroluminescent device, the structure (including the first material layer and the second material layer) of the hole injection layer of the organic electroluminescent device according to the disclosure increases the light emitting efficiency and lifetime of the organic electroluminescent device. Furthermore, compared to the usage of F4-TCNQ as the doping material, the usage of HAT-CN as the doping material enables the organic electroluminescent device to have greater light emitting efficiency and a longer lifetime.

### Experimental Embodiment 2

The purpose of experimental embodiment 2 is to further verify the fact that the structure of the hole injection layer which includes the first material layer and the second material according to the disclosure enhances the light emitting efficiency of the organic electroluminescent device, compared with a convention hole injection layer formed by a single doping layer. Experimental embodiment 1 and comparative embodiment 2 are used for comparison. The organic electroluminescent device according to experimental embodiment 1 has the structure as shown in FIG. 1, wherein the material of the first material layer and the doping material of the second material layer are HAT-CN. A structure of an organic electroluminescent device according to comparative embodiment 2 is similar to the structure shown in FIG. 1, but the organic electroluminescent device according to comparative embodiment 2 has a conventional structure which includes a first electrode layer, a hole injection layer which is formed by only one doping layer, a hole transport layer, a light emitting layer, an electron transport layer, and a second electrode layer, wherein a doping material of the hole injection layer is HAT-CN and the doping concentration is 1.5%.

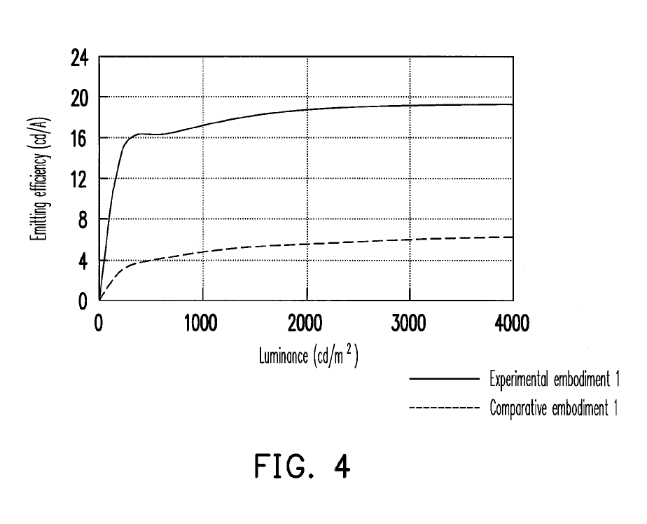

FIG. 4 is a graph illustrating curves which represent light emitting efficiency versus luminance according to experimental embodiment 1 and comparative embodiment 2. According to FIG. 4, the light emitting efficiency of the organic electroluminescent device according to experimental embodiment 1 is significantly greater than the light emitting efficiency of the organic electroluminescent device according to comparative embodiment 2. In other words, the present experiment verifies that compared to a hole injection layer of a conventional organic electroluminescent device, the structure of the hole injection layer which includes the first material layer and the second material layer according to the disclosure increases the light emitting efficiency of the organic electroluminescent device.

In summary, in the organic electroluminescent device according to the disclosure, the hole injection layer includes the first material layer and the second material layer, and the doping material of the second material layer and the material of the first material layer are substantially the same. The material of the first material layer and the doping material (such as the organic material which has the chemical formula of Formula 1) of the second material layer have, for example, a suitable work function value. Therefore, since the first material layer has a lower energy barrier, holes are injected from the first electrode layer (the anode layer) into the hole injection layer more easily, thereby enhancing hole injection efficiency of the hole injection layer. Moreover, the doping material of the second material layer and the material of the first material layer are substantially the same, and the hole concentration of the hole injection layer is increased, so that the device conductivity can be better improved.

According to the disclosure, the structure of the hole injection layer enables the holes to have better mobility, so that the organic electroluminescent device is suitable for a lower device driving voltage and thus prevents an increase in operating voltage, thereby extending the lifetime of the organic electroluminescent device. In particular, the material of the first material layer and the doping material of the second material layer are, for example, more thermally stable and able to be optically processed, so that the hole injection layer is more thermally stable and the film thickness thereof is able to be correctly measured. In other words, the organic electroluminescent device according to the disclosure has better light emitting efficiency, a lower driving voltage, and a longer lifetime.

It will be apparent to those skilled in the art that various modifications and variations can be made to the disclosure without departing from the scope or spirit of the disclosure. In view of the foregoing, it is intended that the disclosure cover modifications and variations of this disclosure provided they fall within the scope of the following claims and their equivalents.

What is claimed is:

1. An organic electroluminescent device, comprising:
a first electrode layer and a second electrode layer;
a light emitting layer, disposed between the first electrode layer and the second electrode layer; and
a hole injection layer, disposed between the first electrode layer and the light emitting layer, wherein the hole injection layer comprises:
a first material layer; and
a second material layer, disposed on the first material layer and comprising a main material and a doping material, wherein the doping material of the second material layer and a material of the first material layer are substantially the same.

2. The organic electroluminescent device as claimed in claim 1, wherein the first material layer and the doping material of the second material layer comprise an organic material.

3. The organic electroluminescent device as claimed in claim 2, wherein the organic material has a chemical formula of Formula 1: 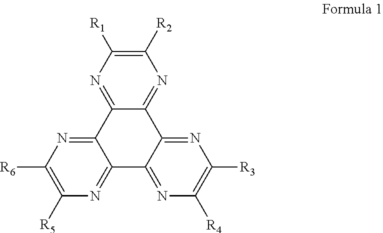
wherein each of R₁-R₆ independently represents hydrogen, a halogen, —CN, —NO₂, —SO₂R, SOR, —CF₃, —CO—OR, —CO—NHR, CO—NRR′, a substituted or non-substituted aryl group, a substituted or non-substituted heteroaryl group, or a substituted or non-substituted alkyl group, and each of R and R′ independently represents a substituted or non-substituted aryl group or a substituted or non-substituted alkyl group, or wherein
R₁ and R₂, R₃ and R₄, or R₅ and R₆ form a ring structure which comprises an aromatic ring, a heteroaromatic ring, or a non-aromatic ring, and the ring structure is substituted or non-substituted.

4. The organic electroluminescent device as claimed in claim 1, wherein the doping material and the material of the first material layer comprise:

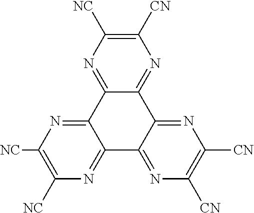

5. The organic electroluminescent device as claimed in claim 1, wherein the main material of the second material layer comprises a triarylamine.

6. The organic electroluminescent device as claimed in claim 1, wherein a content of the doping material in the second material layer is less than 10%.

7. The organic electroluminescent device as claimed in claim 6, wherein the content of the doping material in the second material layer is from 0.5% to 10%.

8. The organic electroluminescent device as claimed in claim 1, wherein a work function value of the first material layer is greater than 5 eV.

9. The organic electroluminescent device as claimed in claim 1, wherein the first material layer contacts the first electrode layer.

10. The organic electroluminescent device as claimed in claim 1, further comprising a hole transport layer, disposed between the hole injection layer and the light emitting layer.

11. The organic electroluminescent device as claimed in claim 1, further comprising an electron transport layer, disposed between the second electrode layer and the light emitting layer.

12. The organic electroluminescent device as claimed in claim 1, further comprising an electron injection layer, disposed between the second electrode layer and the light emitting layer.
